(19) United States
(12) Patent Application Publication
(10) Pub. No.: US 2025/0282979 A1
(43) Pub. Date: Sep. 11, 2025

(54) PHOTONIC DEBONDING FOR WAFER-LEVEL PACKAGING APPLICATIONS

(71) Applicant: Brewer Science, Inc., Rolla, MO (US)

(72) Inventors: Rama Puligadda, Rolla, MO (US); Xiao Liu, Chandler, AZ (US); Luke M. Prenger, Rolla, MO (US); Xavier Martinez, Rolla, MO (US); Vikram Shreeshail Turkani, Austin, TX (US); Vahid Akhavan Attar, Austin, TX (US)

(21) Appl. No.: 19/217,506

(22) Filed: May 23, 2025

Related U.S. Application Data
(63) Continuation of application No. 17/504,272, filed on Oct. 18, 2021, now abandoned.
(60) Provisional application No. 63/092,863, filed on Oct. 16, 2020.
(60) Provisional application No. 63/254,777, filed on Oct. 12, 2021.

(51) Int. Cl. C09J 5/06; C08G 73/02; H01L 21/683

(52) U.S. Cl. CPC C09J 5/06; C08G 73/0233; H01L 21/6836; C09J 2301/502; H01L 2221/68318; H01L 2221/68381

(57) ABSTRACT

A method is described for debonding a carrier and device substrate using a high-intensity, pulsed, broadband light system that is suitable for wafer-level packaging applications. The carrier substrate is a transparent wafer with a light absorbing layer on one side of the wafer. This method utilizes the high intensity light to rapidly heat up the light absorbing layer to decompose or melt a bonding material layer that is adjacent to the light absorbing layer. After exposure to light, the carrier substrate can be lifted off the surface of the device wafer with little or no force.

### RELATED APPLICATIONS

The present application is a continuation of pending U.S. patent application Ser. No. 17/504,272, filed Oct. 18, 20021, entitled PHOTONIC DEBONDING FOR WAFER-LEVEL PACKAGING APPLICATIONS, the entirety of which is incorporated by reference herein. U.S. patent application Ser. No. 17/504,272 claims the priority benefit of U.S. Provisional Patent Application Ser. No. 63/092,863, filed Oct. 16, 2020, entitled PHOTONIC DEBONDING FOR WAFER-LEVEL PACKAGING APPLICATIONS, and U.S. Provisional Patent Application Ser. No. 63/254,777, filed Oct. 12, 2021, entitled PHOTONIC DEBONDING FOR WAFER-LEVEL PACKAGING APPLICATIONS, each of which is incorporated by reference herein in its respective entirety.

### BACKGROUND

### Field

The present disclosure relates to temporary wafer bonding and debonding processes for semiconductor fabrication and packaging.

### Description of Related Art

Temporary wafer bonding (“TWB”) normally refers to a process for attaching a device wafer or microelectronic substrate to a carrier wafer or substrate by means of a polymeric bonding material. After bonding, the device wafer may be thinned, typically to less than 50 μm, and/or processed to create through-silicon vias (“TSV”), redistribution layers, bond pads, and other circuit features on its backside. The carrier wafer supports the fragile device wafer during the backside processing, which can entail repeated cycling between ambient temperature and high temperature (>250° C.), mechanical shocks from wafer handling and transfer steps, and strong mechanical forces, such as those imposed during wafer back-grinding processes used to thin the device wafer. When all of this processing has been completed, the device wafer is usually attached to a film frame and then separated, or debonded, from the carrier wafer and cleaned before further operations take place.

Most TWB processes use either one or two layers between the device substrate and the carrier substrate. Depending on the TWB process, the device and carrier substrate can be separated by a variety of separation methods, such as chemical debonding, thermal slide debonding, mechanical debonding, or laser debonding. Laser debonding is one preferred method for debonding. This method typically utilizes a 300- to 400-nm laser or other light source to ablate a small layer of a polymer that is designed to react to the laser at the wavelength of ablation, causing bonding integrity to be lost within the structure and allowing it to come apart without applying mechanical force. In the case of a two-layer laser debond system, a second polymeric bonding material layer is utilized, typically adjacent to the device surface. The second layer is easily cleaned from the device wafer surface after destruction of the laser-sensitive layer and separation of the bonded wafer pair after processing.

Laser debonding provides advantages such as a low-stress debond, high throughput, flexibility to use two-layer and single-layer material systems, and the ability to use a crosslinked material. Laser debonding is not without disadvantages, however. In order to use this debond mechanism, a carrier substrate that is transparent to the laser wavelength is required, which can cause issues with tool alignment in some situations. Additionally, materials used for laser debond must be reactive with the laser of interest, and if they don't absorb sufficiently at the desired wavelength, there is also a concern of laser energy damaging laser-sensitive devices, which is quite problematic.

### SUMMARY

The present disclosure is broadly concerned with a temporary debonding method. The method comprises providing a stack comprising a device substrate having first and second surfaces, a bonding layer adjacent the first surface, a transparent substrate having front and back surfaces, and a light absorbing layer having first and second sides. The first side of the light absorbing layer is adjacent the front surface of the transparent substrate, and the second side of the light absorbing layer is adjacent the bonding layer. The bonding layer is exposed to a pulse of broadband light so as to facilitate separation of the device substrate and the transparent substrate.

### BRIEF DESCRIPTION OF THE DRAWINGS

FIG. 1(a) is a schematic (not to scale) depiction of a bonding method that can be carried out according to the present description;

FIG. 1(b) is a schematic depiction of the bonded stack formed in FIG. 1(a);

FIG. 1(c) is a schematic depiction of the debonding process wherein one or more photonic light pulses are directed at the stack of FIG. 1(b);

FIG. 1(d) is a schematic depiction of the stack of FIG. 1(c) after separation;

FIG. 2 is a photograph showing one of the debonded wafer pairs from Example 4;

FIG. 3 is a photograph showing a wafer before (left) and after (right) cleaning as described in Example 5;

FIG. 4 is a photograph of a wafer pair after bonding as described in Example 6;

FIG. 5 is a photograph of a pair of wafers that were debonded as described in Example 7;

FIG. 6 is an image of a thin silicon wafer thickness map generated as described in Example 8;

FIG. 7 is a photograph of thinned 6″ wafers after photonic debonding (Example 9); and

FIG. 8 is a photograph of photonically debonded wafers, before (left) and after (right) cleaning, as described in Example 10.

### DETAILED DESCRIPTION

The present disclosure is concerned with a temporary bonding method that debonds using a pulsed light source, such as a flashlamp. This method is useful in microelectronic manufacturing processes, including wafer-level packaging applications.

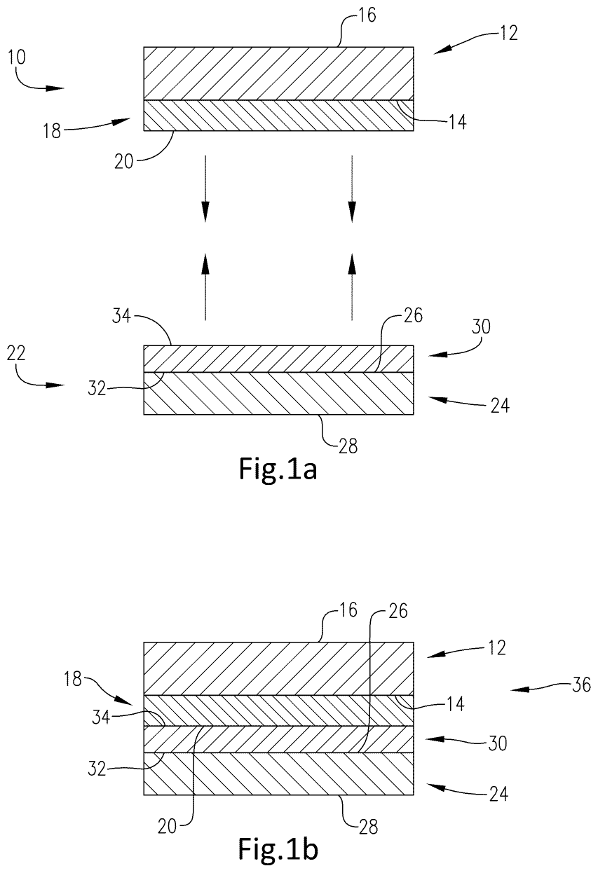

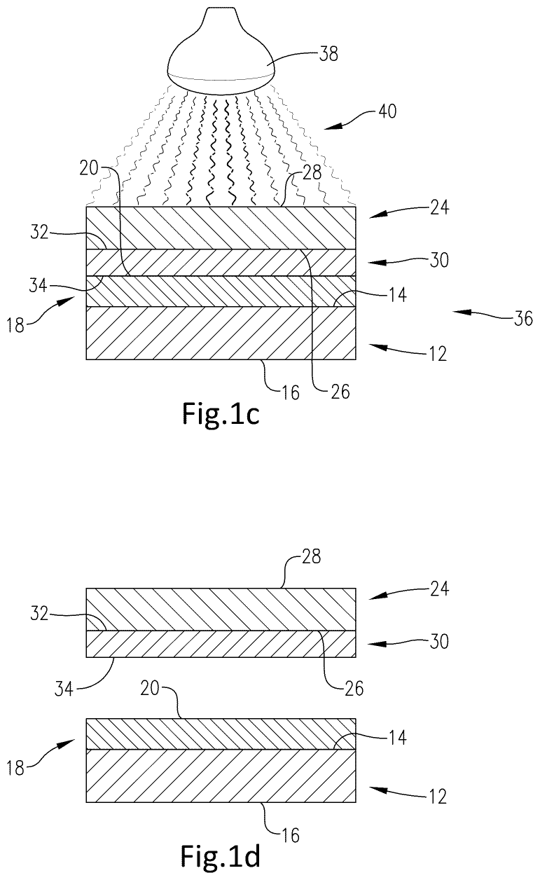

In more detail and referring to FIG. 1(a) (not to scale), a precursor structure 10 is depicted in a schematic and cross-sectional view. Structure 10 includes a device substrate 12. Substrate 12 has a first surface 14 and a second surface 16. Although device substrate 12 can be of any shape, it would typically be circular in shape. Preferred device substrates 12 include device substrates such as those made of silicon, silicon oxide, silicon nitride, silicon oxynitride, silicon-germanium, gallium arsenide, quartz, aluminum, tungsten, tungsten silicide, gallium arsenide, germanium, tantalum, tantalum nitride, Ti₃N₄, hafnium, HfO₂, ruthenium, indium phosphide, glass, or mixtures of the foregoing. Preferred device substrates 12 are those whose device surfaces comprise arrays of devices (not shown) chosen from integrated circuits, MEMS, microsensors, power semiconductors, light-emitting diodes, photonic circuits, interposers, embedded passive devices, and other microdevices fabricated on or from silicon and other semiconducting materials such as silicon-germanium, gallium arsenide, and gallium nitride. The surfaces of these devices commonly comprise structures (again, not shown) formed from one or more of the following materials: silicon, polysilicon, silicon dioxide, silicon oxynitride, metals (e.g., copper, aluminum, gold, tungsten, tantalum), low-k dielectrics, polymer dielectrics, and various metal nitrides and silicides. The device surface of substrate 12 can also include at least one structure chosen from solder bumps, metal posts, metal pillars, and structures formed from a material selected from the group consisting of silicon, polysilicon, silicon dioxide, silicon oxynitride, metal, low-k dielectrics, polymer dielectrics, metal nitrides, and metal silicides.

A bonding composition is applied to the device substrate 12 to form a bonding layer 18 adjacent the first surface 14, as shown in FIG. 1(a). Bonding layer 18 has an upper surface 20 remote from device substrate 12, and preferably, the bonding layer 18 is formed directly on the first surface 14 (i.e., without any intermediate layers between the bonding layer 18 and device substrate 12). The bonding composition can be applied by any known method, with one preferred method being spin-coating the composition at speeds of from about 200 rpm to about 5,000 rpm, preferably from about 500 rpm to about 3,000 rpm for a time period from about 5 seconds to about 120 seconds, preferably from about 30 seconds to about 90 seconds. After the composition is applied, it is preferably heated to a temperature of about 50° C. to about 250° C., and more preferably from about 80° C. to about 220° C. and for time periods from about 60 seconds to about 8 minutes, preferably from about 90 seconds to about 6 minutes. Depending on the composition used to form the bonding layer, baking can also initiate a crosslinking reaction to cure the bonding layer 18. In some embodiments, it is preferable to subject the bonding layer 18 to a multi-stage bake process, depending on the composition utilized. Also, in some instances, the above application and bake process can be repeated on a further aliquot of the composition, so that the bonding layer 18 is “built” on the device substrate 12 in multiple steps. In yet another embodiment, the bonding layer 18 can be provided in the form of a pre-formed, dry film rather than spin-applied. The film then can be adhered to the device substrate 12.

The materials from which the bonding layer 18 is formed should be capable of forming a strong adhesive bond with the device substrate 12. Anything with an adhesion strength of greater than about 15 psig, preferably from about 50 psig to about 250 psig, and more preferably from about 100 psig to about 150 psig, as determined by ASTM D4541/D7234, would be desirable for use as bonding layer 18.

Advantageously, the compositions for use in forming the bonding layer 18 can be selected from commercially available bonding compositions that would be capable of being formed into layers possessing the above adhesive properties, while being removable by heat and/or solvent.

In one embodiment, the bonding layer composition is thermoplastic. Typical such compositions are organic and will comprise a polymer or oligomer dissolved or dispersed in a solvent system with other optional ingredients. The polymer or oligomer is typically selected from a group consisting of polymers and oligomers of cyclic olefins, epoxies, acrylics, silicones, styrenics, vinyl halides, vinyl esters, polyamides, polyimides, polysulfones, polyethersulfones, cyclic olefins, polyolefin rubbers, polyurethanes, ethylene-propylene rubbers, polyamide esters, polyimide esters, polyacetals, polyazomethines, polyketanils, polyvinyl butyrals, and combinations thereof. Typical solvent systems will depend upon the polymer or oligomer selection. Typical solids contents of the compositions will range from about 1% to about 60% by weight, and preferably from about 3% by weight to about 40% by weight, based upon the total weight of the composition taken as 100% by weight.

Preferred thermoplastic compositions will have a complex viscosity at room temperature of at least about 500,000 Pa·s, and more preferably from about 1,000,000 Pa·s to about 3,000,000 Pa·s, and will have a complex viscosity of less than about 15,000 Pa·s, and more preferably from about 500 Pa·s to about 10,000 Pa·s at a temperature of from about 160° C. to about 200° C. Complex viscosity is preferably measured with a rheometer such as that sold under the name AR-2000ex rheometer by TA Instruments.

Preferred thermoplastic compositions should have a thermal decomposition temperature as determined by thermogravimetric analysis of from about 160° C. to about 500° C., more preferably from about 220° C. to about 450° C. Some suitable such compositions are described in U.S. Patent Application Publication Nos. 2008/0173970, 2019/0194453, and 2020/0257202, and U.S. Pat. Nos. 7,935,780, 8,092,628, 8,268,449, 9,496,164, 9,728,439, 9,827,740, 10,103,048, and 10,304,720, each incorporated herein by reference.

In one embodiment, the composition used to form bonding layer 18 is curable and/or crosslinkable. Typically, such compositions are organic and will also comprise a polymer or oligomer dissolved or dispersed in a solvent system with other optional ingredients. The polymer or oligomer is typically selected from a group consisting of polymers and oligomers of cyclic olefins, epoxies, acrylics, silicones, styrenics, vinyl esters, polyamides, polyimides, polysulfones, polyethersulfones, cyclic olefins, polyolefin rubbers, polyurethanes, ethylene-propylene rubbers, polyamide esters, polyazomethines, polyketanils, polyimide esters, and combinations thereof. Typical solvent systems will again depend upon the polymer or oligomer selection. Typical solids contents of the compositions will range from about 1% to about 60% by weight, and preferably from about 3% by weight to about 40% by weight, based upon the total weight of the composition taken as 100% by weight. Preferred crosslinkable compositions will have a complex viscosity at room temperature of at least about 100 Pa·s, more preferably from about 1000 Pa·s to about 30,000 Pa·s, and will have a complex viscosity of less than about 15,000 Pa·s, more preferably from about 100 Pa·s to about 10,000 Pa·s at a temperature of from about 40° C. to about 80° C. Preferred crosslinkable compositions should have a thermal decomposition temperature of from about 160° C. to about 500° C., more preferably from about 220° C. to about 450° C. Some suitable such compositions are described in U.S. Patent Application Publication Nos. 2008/0173970, 2019/0194453, and 2020/0257202, and U.S. Pat. Nos. 7,935,780, 8,092,628, 8,268,449, 9,496,164, 9,728,439, 9,827,740, 10,103,048, and 10,304,720, cach incorporated herein by reference.

In another embodiment, the bonding material may be nonpolymeric (e.g., oligomeric, trimeric, dimeric, monomeric). That is, the structure of the molecule used in this embodiment will have three or fewer repeating subunits, preferably two or fewer repeating subunits, and more preferably only one subunit. When a nonpolymeric bonding material is used, the melting point of the bonding material should be below its sublimation point. In this embodiment, the material preferably has the ability to crosslink or further react in order to prevent material sublimation at high temperatures. Preferred nonpolymeric compositions should have a thermal decomposition temperature of from about 160° C. to about 500° C., more preferably from about 220° C. to about 450° C. Some suitable such compositions are described in U.S. Patent Application Publication No. 2021/0033975, incorporated by reference herein.

Regardless of whether a polymeric or nonpolymeric bonding material is used, the bonding layer 18 preferably possesses the correct balance of mechanical properties required for bonding and debonding. Preferably, the T_{g} of the bonding material is from about 25° C. to about 300° C., more preferably from about 30° C. to about 250° C. If the T_{g} of the material is too low, it may result in the material being too soft, which could cause reattachment of the carrier and device wafer after exposure due to the interfacial heat generation remelting the material or the material having too low of a viscosity at room temperature. If the material has too high of a T_{g}, the material may be too hard and not melt sufficiently to enable bonding. A high T_{g} may also in some instances correlate to a high thermal decomposition. If the thermal decomposition is too high, it may result in no separation between the device and carrier wafers due to insufficient heat being generated at the bonding material-light absorbing layer interface to facilitate the decomposition of the material at the interface.

Regardless of the embodiment, the cured or dried bonding layer 18 should have an average thickness (measured at five locations) of from about 1 μm to about 200 μm, more preferably from about 5 μm to about 100 μm, and even more preferably from about 10 μm to about 50 μm. Thicknesses as used herein can be measured using any film thickness measurement tool, with one preferred tool being an infrared interferometer, such as those sold by SUSS Microtec or Foothill.

The bonding layer 18 should also have a low total thickness variation (“TTV”), meaning that the thickest and thinnest points of the layer 18 are not dramatically different from one another. TTV is preferably calculated by measuring the thickness at a number of points or locations on the film, preferably at least about 50 points or at about 50 points, more preferably at least about 100 points or at about 100 points, and even more preferably at least about 1,000 points or at about 1,000 points. The difference between the highest and lowest thickness measurements obtained at these points is designated the TTV measurement for that particular layer. In some TTV measurement instances, edge exclusion or outliers may be removed from the calculation. In those cases, the number of included measurements is indicated by a percentage, that is, if a TTV is given at 97% inclusion, then 3% of the highest and lowest measurements are excluded, with the 3% split equally between the highest and lowest (i.e., 1.5% each). Preferably, the TTV ranges noted above are achieved using from about 95% to about 100% of the measurements, more preferably from about 97% to about 100% of the measurements, and even more preferably about 100% of the measurements.

A second precursor structure 22 is also depicted in a schematic and cross-sectional view in FIG. 1(a). Second precursor structure 22 includes a transparent substrate 24, which is a carrier wafer. Transparent substrate 24 has a front or carrier surface 26 and a back surface 28. Although transparent substrate 24 can be of any shape, it would typically be circular in shape and sized similarly to device substrate 12. Preferred transparent substrates 24 include clear glass wafers or any other substrate formed of a material that is transparent to photonic energy (i.e., the material will allow the photonic energy to pass through the transparent substrate 24). That is, at least about 50%, preferably at least about 75%, and more preferably at least about 90% of the photonic energy should pass through transparent substrate 24.

Suitable transparent substrates 24 include, but are not limited to, Corning® EAGLE XG® glass wafers (available from Corning Incorporated), Gorilla® Glass (also available from Corning Incorporated), quartz, sapphire, and combinations thereof. The coefficient of thermal expansion (“CTE”) of the transparent substrate 24 will preferably be selected based on the CTE of the device substrate 12. Typical CTE values of the transparent substrate 24 are from about 5×10⁻⁷/K to about 2×10⁻⁵/K, and more preferably from about 1×10⁻⁶/K to about 6×10⁻⁶/K.

A light absorbing layer 30 is applied to the front surface 26 of the transparent substrate 24. Light absorbing layer 30 has a first side 32 and a second side 34, with first side 32 being in contact with front surface 26 of transparent substrate 24. The light absorbing layer 30 preferably comprises a metal, which can be a single metal, two more metals, and/or a metal oxide alloy, depending upon the embodiment. In one embodiment, the light absorbing layer 30 comprises pure metal. In other embodiments, it comprises a mix of metal(s) and other elements, with the total level of metal(s) being at least about 50% by weight, preferably at least about 75% by weight, and more preferably at least about 90% by weight, based on the total weight of the light absorbing layer 30 being taken as 100% by weight.

Any metal that absorbs light at the noted wavelengths and converts it to heat is suitable for use in the present methods. Preferred metals include those chosen from titanium, tungsten, aluminum, copper, gold, silver, iron, tin, zinc, cobalt, chromium, germanium, palladium, platinum, rhodium, manganese, nickel, silicon, tellurium, oxides of the foregoing, alloys of the foregoing, and combinations thereof. Ti/W is particularly preferred for use as light absorbing layer 30.

In one embodiment, light absorbing layer 30 is about 25 nm to about 300 nm thick, and more preferably about 150 nm to about 200 nm thick. The CTE (as measured by thermomechanical analysis) of the light absorbing layer 30 is from about 1×10⁻⁶/K to about 20×10⁻⁶/K, more preferably from about 4.5×10⁻⁶/K to about 4.8×10⁻⁶/K. The transparent substrate 24 and light absorbing layer 30 are preferably chosen to be thermally stable at an elevated temperature and have CTEs that are closely matched in order to mitigate cracking or delamination of light absorbing layer from the carrier when the light absorbing layer is heated. That is, the CTE of the light absorbing layer 30 is within about +/−30%, and more preferably within about +/−10% of the CTE of transparent substrate 24.

The metal can be applied by any suitable method to form light absorbing layer 30, including, but not limited to, sputtering, vapor deposition (“PCVD”), thermal evaporation, atomic layer deposition (“ALD”), and electroplating. One especially preferred light absorbing layer 30 is an approximately 200-nm-thick layer that is about 10% titanium and about 90% tungsten, preferably applied by sputtering.

Structures 10 and 22 are then bonded by pressing them together in a face-to-face relationship, so that upper surface 20 of bonding layer 18 is in contact with second side 34 of light absorbing layer 30 (see FIG. 1(b)). While pressing, sufficient pressure and heat are applied for a sufficient amount of time so as to effect bonding of the two structures 10 and 22 together to form a bonded stack 36. The bonding parameters will vary depending on the bonding composition and substrates, but typical temperatures during this step will range from about 25° C. to about 250° C., and preferably from about 150° C. to about 220° C., with typical pressures ranging from about 1,000 N to about 25,000 N, and preferably from about 3,000 N to about 20,000 N, for a time period of from about 30 seconds to about 20 minutes, and preferably from about 1 minute to about 10 minutes.

The bonded stack 36 should have a TTV of less than about 10% of the total average thickness, preferably less than about 5% of the total average thickness (measured at five locations across the stack), and even more preferably less than about 3% of the total average thickness of the bonded stack 36. That is, if the bonded stack 36 has an average thickness of 100 μm, a TTV of less than about 10% would be about 10 μm or lower.

At this stage, the device substrate 12 can be safely handled and subjected to further processing that might otherwise have damaged the device substrate 12 without being bonded to the transparent substrate 24. Thus, the structure can safely be subjected to backside processing such as backgrinding, PCVD, CMP, etching, metal and dielectric deposition, patterning (e.g., photolithography, via etching), passivation, annealing, die attachment, and combinations thereof, without separation of the device and transparent carrier substrates 12, 24, and without infiltration of any chemistries encountered during these subsequent processing steps. In one embodiment, the device substrate 12 may also be attached to a secondary support substrate, such as a film frame or second carrier substrate (not shown). Not only can the bonding layer 18 survive these processes, it can also survive processing temperatures up to about 400° C., preferably from about 150° C. to 350° C., and more preferably from about 180° C. to about 300° C.

Once processing is complete, the device substrate 12 and carrier substrate 24 can be debonded and separated. As depicted in FIG. 1(c), a light source 38 (e.g., flashlamp and preferably not a laser or any other light source presenting a coherent beam of light) is used to expose back surface 28 of transparent substrate 24 to high-intensity, broadband light 40. Suitable light sources 38 include flashlamps and/or other incoherent light sources that transmit broadband light over a spectrum of wavelengths that preferably range from about 250 nm to about 1,500 nm, and preferably about 250 nm to about 1,000 nm. One especially preferred flashlamp is the NovaCentrix PulseForge® system including a xenon flashlamp described in U.S. Pat. No. 10,986,698 and U.S. patent application Ser. No. 17/122,796, each of which is incorporated by reference herein in its respective entirety.

During exposure, one or more pulses of high intensity light are directed at back surface 28 of transparent substrate 24. That light will pass through transparent substrate 24, contacting light absorbing layer 30, rapidly heating light absorbing layer 30. That is, light absorbing layer 30 has a first temperature immediately prior to the light pulse application, and that light pulse application causes the temperature to increase to a second temperature that is higher than the first temperature. It is preferred that the second temperature be at least about 400° C., more preferably at least about 500° C., even more preferably about 600° C. to about 1,000° C., and most preferably about 650° C. to about 750° C. higher than the first temperature. This temperature increase occurs nearly instantaneously (e.g., less than about 1,000 μs, preferably less than about 750 μs, and more preferably less than about 500 μs). It will be appreciated that this rapid temperature increase causes a small amount of the bonding layer 18 to melt and/or decompose. In one embodiment, neither the light pulsing nor the increase in temperature experienced by light absorbing layer 30 cause any chemical reaction in bonding composition layer 18. Preferably, the light absorbing layer 30 absorbs as much of the light pulse as possible, which can allow the use of a shorter pulse length.

Suitable pulse lengths are preferably from about 40 μs to about 250 μs, and more preferably from about 60 μs to about 150 μs. Advantageously, it is preferred that the number of pulses are five or fewer, more preferably three or fewer, even more preferably two or fewer, and even more preferably only one pulse. It is particularly preferred that this number of pulses be carried out with the pulse length ranges above, in any combination of those ranges.

Suitable voltages are preferably from about 600 V to about 1200 V, and more preferably from about 850 V to about 1050 V. Preferred energy density is from about 2 J/cm² to about 7 J/cm², more preferably from about 2 J/cm² to about 6 J/cm², and even more preferably from about 3.5 J/cm² to about 5 J/cm². Suitable wavelengths for the light pulse are from about 200 nm to about 1,500 nm. The peak radiant power of the light pulse is preferably at least about 20 KW/cm², more preferably at least about 30 KW/cm², and even more preferably at least about 40 KW/cm².

Advantageously, the entire wafer can be exposed at the same time, which can lead to high throughput. That is, the light source 38 can be configured and sized so that the exposure or illumination area is at least the size of the back surface 28 of transparent substrate 24, so that the entire back surface 28 is contacted with the light pulse, as illustrated in FIG. 1(c). If a system is utilized where the lamp has an exposure area that is smaller than the surface area of back surface 28, multiple pulse steps can be carried out, moving either the stack 36 and/or the lamp 38 until all of back surface 28 has been exposed to one or more pulses light. Alternatively, multiple lamps can be configured to create a larger exposure area. For example, one suitable Novacentrix PulseForge® system has a flashlamp that has an exposure area of 150 mm×75 mm. Two or more lamps could be placed in parallel to increase that area in increments of 75 mm.

In a preferred embodiment, the exposure area is selected based on the diameter of the substrates 12 and/or 24. Thus, for a 4″ substrate, the exposure area is preferably about 81 cm² or greater, and about 182 cm² or greater for a 6″ substrate. The exposure area is preferably about 324 cm² or greater for an 8″ substrate and about 729 cm² or greater for a 12″ substrate.

In another embodiment, the back surface 28 of transparent substrate 24 has a total surface area, and the exposure area of light that contacts back surface 28 is at least about 40%, preferably at least about 50%, more preferably at least about 75%, and most preferably at least about 90% of the total surface area of back surface 28.

After exposure to the high-intensity light, the light absorbing layer 30 rapidly cools down, and the transparent substrate 24 and device substrate 12 can be separated using little to no force, mechanical or otherwise. In preferred embodiments, gravity alone can be used to cause this separation. Regardless, it is preferred that separation occurs within about 5 seconds or less, preferably within about 3 seconds or less, and more preferably within about 1 second or less after light exposure was commenced.

Separation results in transparent substrate 24 with the light absorbing layer 30 removed from the device substrate 12, leaving the device substrate 12 with the bonding composition layer 18 and separately the transparent substrate 24 with the light absorbing layer 30 as shown in FIG. 1(d). In some applications, it may be necessary to attach the device substrate 12 to a dicing tape or similar structure.

After separation, any remaining bonding layer 18 can be removed with a plasma etch or a solvent capable of dissolving the bonding layer. For the plasma cleaning, O₂ plasma may be used alone, or a combination of O₂ plasma and fluorinated gas in a ratio of from about 1:1 to about 10:1 may be used, at a power of 100 W and higher. Solvent cleaning can be performed by bath or spin cleaning process. Suitable solvents for nonpolar bonding materials include, for example, d-limonene, mesitylene, 1-dodecene, and combinations thereof. Suitable solvents for cleaning polar bonding materials include gamma-butyrolactone (“GBL”), cyclopentanone, benzyl alcohol, dimethylsulfoxide (“DMSO”), cyclohexanone, propylene glycol methyl ether (“PGME”), propylene glycol methyl ether acetate (“PGMEA”), n-methyl-2-pyrrolidone (“NMP”), 1,3-dioxolane, and combinations thereof. When a spin cleaning process is used, it is preferably performed from about 1 minute to about 15 minutes of clean time. In the spin cleaning process, solvent is sprayed in the center of the wafer with a combination of puddle and soak cycle and then is spun off. For a puddle and soak cycle, solvent is sprayed in the center of the wafer and puddled out at a spin speed of from about 20 rpm to about 150 rpm and is soaked with no solvent spraying or rotation of the wafer for from about 30 seconds to about 90 seconds. In the final step, solvent is dispensed in the center of the substrate and the substrate is spun at a spin speed of from about 750 rpm to about 1,500 rpm.

The transparent substrate 24 with the light absorbing layer 30 may also be reused with a minor cleaning process by solvent or dry etch. When a solvent clean is used, a spin cleaning process can be used with solvents including, for example, cyclopentanone, GBL, cyclohexanone, d-limonene, acetone, isopropyl alcohol, mestilyene, PGMEA, PGME, NMP, 1,3-dioxolane, benzyl alcohol, DMSO, and combinations thereof. The transparent carrier substrate 24 can be cleaned for a total time of from about 5 seconds to about 120 seconds, more preferably from about 15 seconds to about 45 seconds. When a dry etch is used, gas types such as O₂, argon, CF₄, N₂ and combinations thereof can be used. Suitable parameters for the dry etch cleaning process include a power of from about 50 W to about 2,000 W, more preferably from about 150 W to about 1250 W; a time of from about 5 seconds to about 90 seconds, more preferably from about 10 seconds to about 60 seconds; a pressure of less than about 150 mTorr; and a gas flow rate of from about 10 sccm to 300 sccm, more preferably from about 20 sccm to about 100 sccm.

In the above-described process, the bonding layer 18 was formed on the first surface 14 of device substrate 12. It will be appreciated that bonding layer 18 could be formed on second side 34 of light absorbing layer 30, and then device substrate 12 could be bonded to bonding layer 18.

In a substrate flip process, the bonding layer 18 could be formed on the second surface 16 of device substrate 12 instead of on first surface 14 as shown in FIG. 1(a). In this substrate flip process, the structure 10 would still be bonded to the structure 22 through bonding layer 18.

In a further variation, one or both of structures 10 or 22 could be provided “preformed,” so that the device manufacture does not have to form one or both of the bonding layer 18 or light absorbing layer 30 on-site.

It will be appreciated that the disclosed methods provide significant advantages over prior art methods. For example, the inventive methods provide for low force and low stress on devices during the debond process. Additionally, the disclosed method is extremely fast compared to prior art debond methods as debonding can take place within seconds compared to minutes for prior art debond methods. Furthermore, the use of Ti/W or other metals in or as the light absorbing layer 30 in some embodiments can assist with sensor tool alignment. Finally, there is a wide variety of materials that can be utilized as bonding layer 18, due to that layer not requiring low adhesion to another material or requiring reaction with a laser.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### 4″ Wafer Preparation for Photonic Debonding Testing

An experimental phenoxy-based bonding material (“Material A,” Brewer Science, Inc., Rolla, MO) was coated on a 4″ silicon wafer by spin-coating at 1,000 rpm for 30 seconds with an acceleration of 3,000 rpm/s, followed by baking at 60° C. for 5 minutes, then 160° C. for 5 minutes, and then 220° C. for 5 minutes. The wafer was then bonded to the center of a 6″×6″ square glass panel with a Ti/W sputter coating on one side of the square panel. The wafers were bonded with the coated side of the wafer facing the Ti/W side of the panel at 220° C. and 2,000 N for 3 minutes, using an Apogee™ Bonder. The bonded stack showed high adhesion and was not able to be manually separated by insertion of a razor blade.

### Example 2

### 4″ Wafer Preparation for Photonic Debonding Testing

A commercially available bonding material (BrewerBOND® 305, hereinafter “Material B,”

Brewer Science, Inc., Rolla, MO) was coated on a 4″ silicon wafer by spin-coating at 1,000 rpm for 30 seconds with an acceleration of 500 rpm/s and was baked at 60° C. for 3 minutes, then 160° C. for 3 minutes, and then 220° C. for 3 minutes. The wafer was then bonded to the center of a 6″×6″ square glass panel with Ti/W sputter coating on one side of the square panel. The wafers were bonded with the coated side of the wafer facing the Ti/W side of the panel at 220° C. and 1,800 N for 3 minutes, using an Apogee™ Bonder. The bonded stack showed high adhesion and was not able to be separated by manual separation by insertion of a razor blade.

### Example 3

### 4″ Wafer Preparation for Photonic Debonding Testing

An experimental polyester-based bonding material (“Material C,” Brewer Science, Inc., Rolla, MO) was coated on a 4″ silicon wafer by spin-coating at 650 rpm for 30 seconds with an acceleration of 500 rpm/s and was baked at 80° C. for 3 minutes, then 160° C. for 3 minutes, and then 200° C. for 6 minutes. The wafer was then bonded to the center of a 6″×6″ square glass panel with Ti/W sputter coating on one side of the square panel. The wafers were bonded with the coated side of the wafer facing the Ti/W side of the panel at 140° C. and 1,000 N for 3 minutes, using an Apogee™ Bonder. The bonded stack showed high adhesion and was not able to be manually separated by insertion of a razor blade.

### Example 4

### Photonic Debonding Separation of Bonded Wafers

The bonded stacks prepared in Examples 1, 2, and 3 were debonded using a NovaCentrix PulseForge® 3300 Photonic Curing System configured with an exposure area that covered the entire surface of the 4″ carrier wafers in a single pulse. Table 1 shows the results and process conditions used to photonically debond the bonded stacks.

TABLE 1
Process Conditions for 4″ Wafer Pairs After Photonic Debond Process

| | | Pulse | Pulse | Measured | | | |
|---|---|---|---|---|---|---|---|
| | Voltage | Length | Shape | Energy Density | Adhesion | Wafer | |
| Material | (V) | (μs)* | Notes | (J/cm²) | Loss | Separation | Notes |
| Material A -Wafer 1 | 950 | 110 | 1× | 4.02 | Yes | Yes | Exposed Three |
| | | | | | | | Times** |
| Material A -Wafer 2 | 950 | 110 | 1× | 4.02 | Yes | No | |
| Material B - Wafer 1 | 950 | 130 | 1× | 4.99 | Yes | Yes | |
| Material B - Wafer 2 | 950 | 110 | 1× | 4.02 | No | No | |
| Material C - Wafer 1 | 950 | 110 | 1× | 4.02 | Yes | No | |

*Only a single pulse was utilized, unless specified otherwise.
**Three rounds of single pulses.

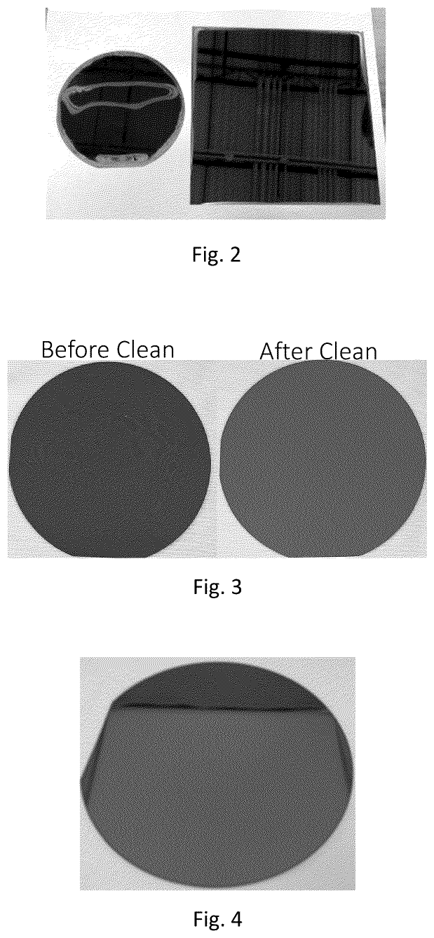

As used in Table 1, the term “adhesion loss” refers to the material losing adhesion with the Ti/W sputtered substrate, but still is adhered by static. “Wafer separation” refers to the wafer no longer having any form of static adhesion to the substrate and able to be removed by simply flipping the substrate over. FIG. 2 shows the image of a successfully separated bonded pair where Material A was used as the bonding material.

### Example 5

### Cleaning of Photonic Debonded Samples From Example 4

The debonded samples from Example 4 were evaluated for cleaning to verify that the material could be removed from the Si wafer after the photonic exposure process. For this testing, Material A and Material C were cleaned using a spin cleaning process, while Material B was cleaned utilizing a soak process.

The Material B wafer was soaked for 12 hours in D-limonene, and then rinsed with a small amount of D-limonene and acetone for drying the wafer. After the wafer was dry, no polymer residue was observed upon visual inspection.

The Material A and Material C were both spin cleaned using cyclopentanone that involved spraying a consistent stream of cyclopentanone on the wafers for 2 minutes followed by washing with IPA for 15 seconds and then spin drying for 15 seconds. The wafers were visually inspected and showed no polymer residue remaining on the surface. FIG. 3 shows an example of the wafers before and after cleaning by this cyclopentanone and IPA cleaning process.

### Example 6

### 6″ Wafer Preparation for Photonic Debonding Testing

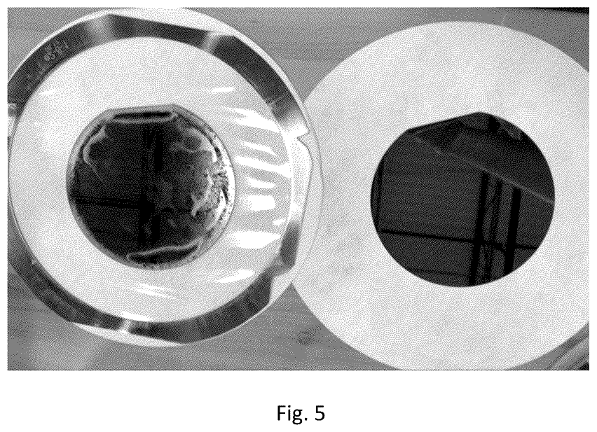

Materials A and C were coated on 6″ silicon wafers and bonded to 6″ Ti/W sputtered glass wafers using the same processes as in Examples 1 and 3, respectively. FIG. 4 shows an example of a bonded pair bonded using Material C. The wafers were then put on a film frame before evaluating a debond process.

### Example 7

### Photonic Debonding Separation of Example 6 Bonded Wafers

The bonded wafer pairs prepared in Example 6 were debonded using a NovaCentrix PulseForge® 3300 Photonic Curing System configured with an exposure area that covered the entire surface of the 6″ carrier wafers in a single pulse. During this evaluation, the wafers were also put on a film frame with a tape backer to simulate wafer support that takes place in many semiconductor manufacturing processes, verifying there would be no problem utilizing a film frame for these wafers. During the exposure, the film frame was masked and did not show any problems with the exposure process. Table 2 shows the results and process conditions used to photonically debond the bonded stacks. FIG. 5 shows the image of a successfully separated pair with the Si wafer on the film frame that had been bonded with Material C.

TABLE 2
Process Conditions for 6″ Wafer Pairs After Photonic Debond Process

| | | Pulse | Pulse | Measured | | | |
|---|---|---|---|---|---|---|---|
| | Voltage | Length | Shape | Energy Density | Adhesion | Wafer | |
| Material | (V) | (μs)* | Notes | (J/cm²) | Loss | Separation | Notes |
| Material A - Wafer 2 | 950 | 130 | 1× | 4.99 | Yes | Yes | |
| Material A - Wafer 3 | 950 | 150 | 1× | 6.00 | Yes | Yes | |
| Material C - Wafer 1 | 950 | 130 | 1× | 4.99 | Yes | Yes | Exposed three |
| | | | | | | | times for |
| | | | | | | | process tuning** |
| Material C - Wafer 2 | 950 | 130 | 1× | 4.99 | Yes | No | |
| Material C - Wafer 3 | 950 | 150 | 1× | 6.00 | Yes | Yes | |

*Only a single pulse was utilized, unless specified otherwise.
**Three rounds of single pulses.

### Example 8

### 6″ Thinned Wafer Preparation for Photonic Debonding Testing

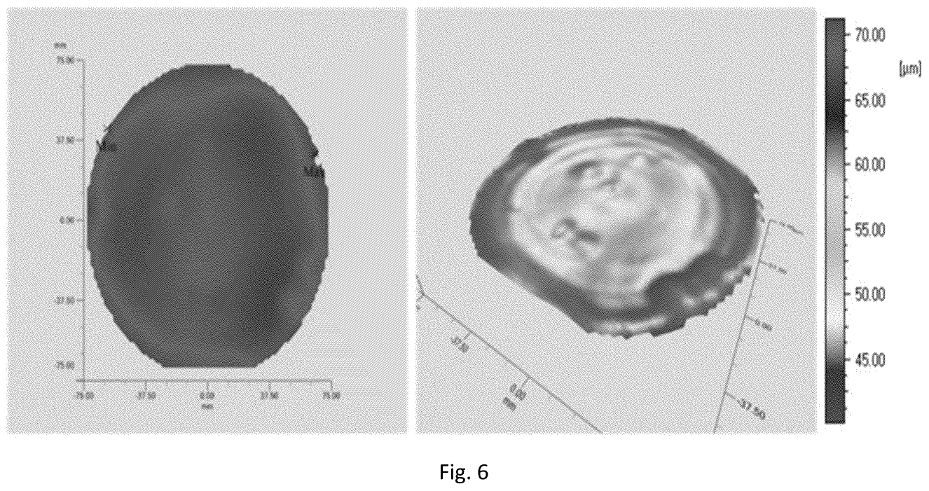

Materials A and C were coated on 6″ tight TTV silicon wafers (total thickness variation of less than 2 μm) and bonded with 6″ Ti-/W-sputtered glass wafers using the same processes as in Examples 1 and 3, respectively. After the bonding process, the wafer pairs were subjected to backside grinding with the silicon wafers being thinned down to a target thickness of 70 μm. After being thinned to 70 μm, the silicon thickness of the wafer pairs was inspected using an IRT sensor (i.e., an interferometric film thickness sensor) on an FRT microProf 300 metrology tool (from FormFactor, Inc.) to confirm the average thickness value of the thinned silicon. The average thickness of the wafers was 67.9 μm. The thinned wafer thickness map for wafers bonded using Material A can be seen in FIG. 6.

### Example 9

### Photonic Debonding Separation of Example 8 Thinned Bonded Wafers

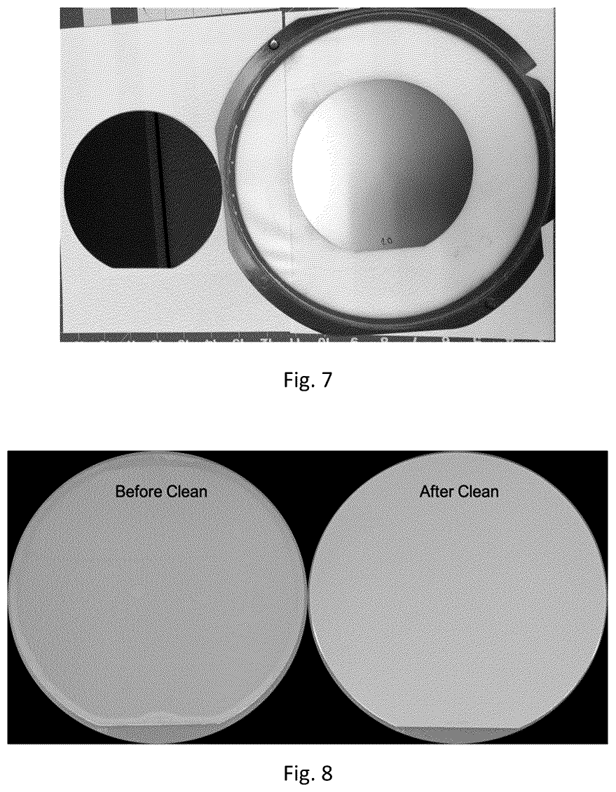

The bonded wafer pairs prepared in Example 8 were debonded using a NovaCentrix PulseForge® 3300 Photonic Curing System configured with an exposure area that covered the entire surface of the 6″ carrier wafers in a single pulse. During this evaluation, the wafers were also put on a film frame with a tape backer to support the thin wafer. During the exposure, the film frame was masked and did not show any problems with the exposure process. Table 3 shows the results and process conditions used to photonically debond the bonded stacks of Material A and C. FIG. 7 shows the image of a successfully separated bonded pair that had been bonded with Material A with the thin Si wafer on the film frame and backside of the silicon showing with no cracks observed.

TABLE 3
Process Conditions for thinned 6″
Wafer Pairs for Photonic Debond Process

| | | Pulse | Pulse | Pulse | |
|---|---|---|---|---|---|
| | | Voltage | Duration | Shape | Fluence |
| Wafer | Material | (V) | (μs)* | Notes | (J/cm²)** |
| 1 | Material C | 700 | 400 | 2.0OF, | 6.06 |
| | | | | 2.5 m/min | |
| 2 | Material C | 700 | 400 | 1.4OF, | 6.06 |
| | | | | 2.5 m/min | |
| 3 | Material C | 700 | 400 | 1.4 OF, | 6.06 |
| | | | | 2.5 m/min | |
| 4 | Material C | 700 | 400 | 1.4 OF, | 6.06 |
| | | | | 2.5 m/min | |
| 5 | Material C | 700 | 390-400 | 1.4 OF, | 5.81-6.06 |
| | | | | 2.5 m/min | |
| 6 | Material C | 950 | 140-200 | 1.4OF, | 3.95-6.04 |
| | | | | 2.5 m/min | |
| 7 | Material A | 750 | 300 | 1.4OF, | 5.32 |
| | | | | 2.5 m/min | |
| 8 | Material A | 750 | 300 | 1.4OF, | 5.32 |
| | | | | 2.5 m/min | |
| 9 | Material A | 750 | 290-300 | 1.4OF, | 4.8-5.32 |
| | | | | 2.5 m/min | |
| 10 | Material A | 750 | 300 | 1.4OF, | 5.32 |
| | | | | 2.5 m/min | |
| 11 | Material A | 950 | 180 | 1.2-1.4OF, | 5.34 |
| | | | | 2.5 m/min | |
| 12 | Material A | 950 | 160-190 | 1.4OF, | 4.63-5.69 |
| | | | | 2.5 m/min | |

*Only a single pulse was utilized, unless specified otherwise.
**Also referred to as energy density.

### Example 10

### Cleaning of Photonically Debonded Wafers From Example 9

A debonded wafer from Example 9 (one that had been bonded with Material A) was cleaned using a spin cleaning process with a pressure pod dispense system. Specifically, the wafer was cleaned using a 3-step cleaning process with cyclopentanone as the cleaning solvent. IPA was used as a solvent to assist in the drying of the wafer. The conditions used to clean the thin Si wafer are shown in Table 4. After cleaning, the thin Si wafer was visually inspected for cleanliness. These images are shown in FIG. 8.

TABLE 4
Cleaning Process Conditions for Material A
from Photonically Debonded Thin Si Wafer

| Step | Spin Speed (rpm) | Time (s) | Solvent Dispense |
|---|---|---|---|
| 1 | 1,000 | 130 | Cyclopentanone |
| 2 | 1,000 | 15 | IPA |
| 3 | 1,000 | 15 | No Solvent |

We claim:

1. A temporary bonding method comprising:
providing a stack comprising:
a device substrate having first and second surfaces;
a bonding layer adjacent said first surface;
a transparent substrate having front and back surfaces; and
a light absorbing layer having first and second sides, said first side being adjacent said front surface and said second side being adjacent said bonding layer; and
exposing said light absorbing layer to a pulse of broadband light so as to facilitate separation of said device substrate and said transparent substrate.

2. The method of claim 1, wherein said exposing is carried out by a flashlamp.

3. The method of claim 1, wherein said exposing comprises applying said pulse of broadband light to the back surface of said transparent substrate.

4. The method of claim 3, where said back surface of said transparent surface has a total surface area, and said broadband light has an exposure area that is at least about 40% of said total surface area.

5. The method of claim 1, wherein said pulse of broadband light is transmitted over a plurality of wavelengths of about 200 nm to about 1,500 nm.

6. The method of claim 1, wherein said light absorbing layer has a first temperature immediately prior to said exposing and said exposing causes the temperature of said light absorbing layer to increase to a second temperature.

7. The method of claim 1, wherein said exposing causes a softening of said bonding layer so as to facilitate said separation.

8. The method of claim 1, wherein said exposing does not cause any chemical reactions in said bonding layer.

9. The method of claim 1, wherein said separation occurs within about 5 seconds or less of said exposing.

10. The method of claim 1, wherein the source of said pulse of broadband light is not a laser.

11. The method of claim 1, wherein said separation occurs without the application of mechanical force to either the device substrate or the transparent substrate.

12. The method of claim 1, wherein said light absorbing layer comprises metal.

13. The method of claim 12, wherein said metal is chosen from titanium, tungsten, aluminum, copper, gold, silver, iron, tin, zinc, cobalt, chromium, germanium, palladium, platinum, rhodium, manganese, nickel, tellurium, oxides of the foregoing, alloys of the foregoing, and combinations thereof.

14. The method of claim 1, wherein said providing comprises forming said bonding layer on said first surface and then contacting said bonding layer with said second side of said light absorbing layer so as to form said stack.

15. The method of claim 1, wherein said providing comprises forming said light absorbing layer on said front surface of said transparent substrate and then contacting the second side of said light absorbing layer with said bonding layer so as to form said stack.

16. The method of claim 1, further comprising, prior to said exposing, subjecting said stack to processing chosen from back-grinding, chemical-mechanical polishing, etching, metallizing, dielectric deposition, patterning, passivation, annealing, redistribution layer formation, and combinations thereof, prior to separating said device substrate and transparent substrate.

17. The method of claim 1, wherein at least one of said first and second surfaces of said device substrate comprises one or more of:
(1) an array of devices chosen from: integrated circuits; MEMS; microsensors; power semiconductors; light-emitting diodes; photonic circuits; interposers; embedded passive devices; and microdevices fabricated on or from silicon, silicon-germanium, gallium arsenide, or gallium nitride; or
(2) at least one structure chosen from: solder bumps; metal posts; metal pillars; and structures formed from a material selected from the group consisting of silicon, polysilicon, silicon dioxide, silicon (oxy)nitride, metal, low k dielectrics, polymer dielectrics, metal nitrides, or metal silicides.

18. The method of claim 1, wherein said bonding layer comprises one or more of:
(1) uncrosslinked polymers or oligomers of cyclic olefins, epoxies, acrylics, silicones, styrenics, vinyl halides, vinyl esters, polyamides, polyimides, polysulfones, polyethersulfones, cyclic olefins, polyolefin rubbers, polyurethanes, ethylene-propylene rubbers, polyamide polyimide esters, polyacetals, polyazomethines, polyketanils, polyvinyl butyrals, or combinations thereof; or
(2) crosslinked polymers or oligomers of cyclic olefins, epoxies, acrylics, silicones, styrenics, vinyl esters, polyamides, polyimides, polysulfones, polyethersulfones, cyclic olefins, polyolefin rubbers, polyurethanes, ethylene-propylene rubbers, polyamide esters, polyazomethines, polyketanils, polyimide esters, or combinations thereof.

19. The method of claim 1, wherein said pulse of broadband light has a pulse length of about 40 μs to about 250 μs.

20. The method of claim 1, wherein the energy density during said exposing is about 2 J/cm² to about 7 J/cm².

21. The method of claim 1, wherein said exposing comprises exposing said bonding layer to five or fewer pulses of broadband light.

22. The method of claim 6, wherein said second temperature is at least about 400° C. higher than said first temperature.

23. The method of claim 22, wherein said light absorbing layer increases to said second temperature within about 1,000 μs or less of said exposing.

24. The method of claim 1, wherein said light absorbing layer comprises Ti/W.

25. The method of claim 24, wherein said light absorbing layer comprises about 10% titanium and about 90% tungsten.

26. The method of claim 1, wherein said bonding layer is a thermoplastic layer.

27. The method of claim 1, wherein said bonding layer is formed on said first surface of said substrate by spin coating.
